(19) United States
(12) Patent Application Publication
(10) Pub. No.: US 2024/0053672 A1
(43) Pub. Date: Feb. 15, 2024

(54) MASK BLANK, METHOD FOR MANUFACTURING TRANSFER MASK, AND METHOD FOR MANUFACTURING SEMICONDUCTOR DEVICE

(71) Applicant: HOYA CORPORATION, Tokyo (JP)

(72) Inventors: Hiroaki SHISHIDO, Tokyo (JP); Osamu NOZAWA, Tokyo (JP)

(73) Assignee: HOYA CORPORATION, Tokyo (JP)

(21) Appl. No.: 18/270,789

(22) PCT Filed: Jan. 18, 2022
(86) PCT No.: PCT/JP2022/001582

§ 371 Date: Jul. 3, 2023

(30) Foreign Application Priority Data
Jan. 26, 2021 (JP) 2021-010359

(51) Int. Cl. G03F 1/32

(52) U.S. Cl. CPC G03F 1/32

(57) ABSTRACT

A mask blank has a substrate and a pattern-forming thin film formed on the substrate. The pattern-forming thin film is one of a single-layer film containing chromium and nitrogen or a multi-layer film comprising at least one chromium nitride-based layer. An arithmetic mean roughness Sa is 1.0 nm or less and a ratio of a maximum height Sz to the arithmetic mean roughness Sa Sz/Sa is 14 or less in a 1-μm square positioned in a central region on a surface of the pattern-forming thin film with respect to a center of the substrate.

### CROSS-REFERENCE TO RELATED APPLICATIONS

This application is the National Stage of International Application No. PCT/JP2022/001582, filed Jan. 18, 2022, which claims priority to Japanese Patent Application No. 2021-010359, filed Jan, 26, 2021, and the contents of which is incorporated by reference.

### TECHNICAL FIELD

The present disclosure relates to a mask blank, a method for manufacturing a transfer mask using the mask blank, and a method for manufacturing a semiconductor device using the transfer mask manufactured by the above-mentioned manufacturing method.

### BACKGROUND ART

Generally, in a manufacturing process of a semiconductor device, a fine pattern is formed using a photolithography method. In forming the fine pattern, a large number of substrates called transfer masks (photomasks) are commonly used. The transfer mask generally has a fine pattern formed on a transparent glass substrate and comprising a thin metal film or the like. In manufacture of the transfer mask, the photolithography method is used also.

The transfer mask serves as an original plate for transferring the same fine pattern in large quantities. Therefore, dimensional accuracy of the pattern formed on the transfer mask directly affects dimensional accuracy of a fine pattern to be formed using the transfer mask. In recent years, there is a remarkable progress in miniaturization of a pattern of the semiconductor device. Correspondingly, the mask pattern formed on the transfer mask is required to be miniaturized and to have higher pattern accuracy. On the other hand, in addition to the miniaturization of the pattern on the transfer mask, there is a progress in shortening a wavelength of an exposure light source used in photolithography. Specifically, with respect to the exposure light source used in manufacture of the semiconductor device, shortening of the wavelength advances from a KrF excimer laser (wavelength of 248 nm) to an ArF excimer laser (wavelength of 193 nm) in recent years.

As a type of the transfer mask, in addition to a binary mask having a light-shielding film pattern formed on a transparent substrate and made of a chromium-based material (for example, see Patent Document 1), a halftone phase shift mask, for example, is known (for example, see Patent Document 2). The halftone phase shift mask has a light semi-transmissive film pattern on a transparent substrate. The light semi-transmissive film (halftone phase shift film) has a function of transmitting light at a strength that does not substantially contribute to exposure and of generating a predetermined phase difference in the light transmitted through the light semi-transmissive film with respect to light passing through air by the same distance, thereby generating a so-called phase shift effect.

### PRIOR ART DOCUMENT (S)

### Patent Document (s)

Patent Document 1: JP 2001-305713 A

Patent Document 2: WO 2004/090635 A1

### SUMMARY OF THE DISCLOSURE

### Problem to be Solved by the Disclosure

As described above, in recent years, miniaturization of the mask pattern remarkably progresses, and it is required to form a fine pattern having a size of, for example, 50 nm or less with high pattern accuracy. In order to obtain a transfer mask having such a fine pattern formed with high pattern accuracy, a high-quality mask blank, for example, having less surface defects is required as a mask blank used for manufacture of the transfer mask. For example, the mask blank has a pattern-forming thin film on a substrate. Even if a defect existing on a surface of the pattern-forming thin film is a microdefect (convex defect) having a low height and a small size, an adverse effect is possibly imposed on forming the above-mentioned fine pattern with high pattern accuracy.

In recent years, a most-advanced defect inspection apparatus using inspection light having a wavelength of 193 nm has become used for defect inspection of the mask blank. When the defect inspection is performed by such a defect inspection apparatus, there may arise a problem that, even if the defects existing on the surface of the pattern-forming thin film of the mask blank are microdefects, the inspection stops in the middle of the inspection (overflow) when the number of the defects is very large.

The present disclosure has been made in view of the above-mentioned problems in the existing technology. A first aspect of the present disclosure is to provide a mask blank which has a structure including a pattern-forming thin film formed on a substrate and which has less microdefects on a surface of the pattern-forming thin film.

A second aspect of the present disclosure is to provide a mask blank which does not impose an adverse effect when defect inspection of the mask blank is carried out by using a most-advanced defect inspection apparatus as described above.

A third aspect of the present disclosure is to provide a method for manufacturing a transfer mask with a high-accuracy fine transfer pattern by using the above-mentioned mask blank.

A fourth aspect of the present disclosure is to provide a method for manufacturing a semiconductor device, which is capable of performing high-accuracy pattern transfer to a resist film on a semiconductor substrate using the above-mentioned transfer mask.

### Means to Solve the Problem

As a result of continuing extensive studies in order to solve the above-mentioned problems, the present inventors have completed the present disclosure.

Specifically, in order to solve the above-mentioned problems, the present disclosure has the following configurations.

### (Configuration 1)

A mask blank having a substrate and a pattern-forming thin film formed on the substrate,

wherein the pattern-forming thin film is a single-layer film containing chromium and nitrogen or a multi-layer film including a chromium nitride-based layer containing chromium and nitrogen; and

wherein, when a central region is defined on a surface of the pattern-forming thin film as an inner region of 1-μm square positioned with respect to a center of the substrate and an arithmetic mean roughness Sa and a maximum height Sz are measured in the central region, Sa is 1.0 nm or less and Sz/Sa is 14 or less.

### (Configuration 2)

The mask blank according to Configuration 1, wherein, when eight adjacent regions, each of which is an inner region of 1-μm square and which do not overlap each other, are defined on the surface of the pattern-forming thin film to be in contact with an outer periphery of the central region and to surround the entirety of the periphery and the arithmetic mean roughness Sa and the maximum height Sz are measured in all of the adjacent regions, all values of Sa are 1.0 nm or less and all values of Sz/Sa are 14 or less.

### (Configuration 3)

The mask blank according to Configuration 1 or 2, wherein the maximum height Sz of the central region is 10 nm or less.

### (Configuration 4)

The mask blank according to any one of Configurations 1 to 3, wherein a root-mean-square roughness Sq of the central region is 1.0 nm or less.

### (Configuration 5)

The mask blank according to any one of Configurations 1 to 4, wherein, when the surface of the pattern-forming thin film is subjected to defect inspection by a defect inspection apparatus using inspection light having a wavelength of 193 nm to obtain distribution of convex defects in a pattern-forming region which is an inner region of 132-mm square, microdefects being the convex defects having a height of 10 nm or less are present in the pattern-forming region and the number of the microdefects present in the pattern-forming region is 100 or less.

### (Configuration 6)

The mask blank according to any one of Configurations 1 to 5, wherein a content of nitrogen in a portion of the single-layer film excluding a surface layer on the side opposite from the substrate is 8 atomic % or more, or a content of nitrogen in the chromium nitride-based layer of the multi-layer film is 8 atomic % or more.

### (Configuration 7)

The mask blank according to any one of Configurations 1 to 6, wherein a content of chromium in the portion of the single-layer film excluding a surface layer on the side opposite from the substrate is 60 atomic % or more, or a content of chromium in the chromium nitride-based layer of the multi-layer film is 60 atomic % or more.

### (Configuration 8)

The mask blank according to any one of Configurations 1 to 7, wherein the multi-layer film includes a hard mask layer containing silicon and oxygen on the chromium nitride-based layer.

### (Configuration 9)

The mask blank according to any one of Configurations 1 to 7, wherein the multi-layer film includes an upper layer containing chromium, oxygen and nitrogen on the chromium nitride-based layer

### (Configuration 10)

The mask blank according to Configuration 9, wherein the multi-layer film includes a hard mask layer containing silicon and oxygen on the upper layer.

### (Configuration 11)

The mask blank according to any one of Configurations 1 to 10, further comprising a phase shift film between the substrate and the pattern-forming thin film.

### (Configuration 12)

The mask blank according to Configuration 11, wherein the phase shift film has a function of transmitting exposure light of an ArF excimer laser (wavelength of 193 nm) at a transmittance of 8% or more, and a function of generating a phase difference of 150 degrees or more and 210 degrees or less between the exposure light transmitted through the phase shift film and the exposure light passing through air by the same distance as a thickness of the phase shift film.

### (Configuration 13)

The mask blank according to Configuration 11 or 12, wherein an optical density with respect to exposure light of an ArF excimer laser (wavelength of 193 nm) is 3.3 or more in a stacked structure of the phase shift film and the pattern-forming thin film.

### (Configuration 14)

A method of manufacturing a transfer mask using the mask blank according to any one of Configurations 1 to 10, including:
a step of forming a transfer pattern on the pattern-forming thin film by dry etching using a resist film having a transfer pattern as a mask.

### (Configuration 15)

A method of manufacturing a transfer mask using the mask blank according to any one of Configurations 11 to 13, including:
a step of forming a transfer pattern on the pattern-forming thin film by dry etching using a resist film having a transfer pattern as a mask, and
a step of forming a transfer pattern on the phase shift film by dry etching using the pattern-forming thin film having the transfer pattern as a mask.

### (Configuration 16)

A method of manufacturing a semiconductor device, including a step of carrying out exposure transfer of a transfer pattern to a resist film on a semiconductor substrate by using a transfer mask obtained by the method of manufacturing a transfer mask according to Configuration 14 or 15.

### Effect of the Disclosure

A mask blank according to the present disclosure has a structure including a pattern-forming thin film on a substrate, wherein the pattern-forming thin film is a single-layer film containing chromium and nitrogen or a multi-layer film including a chromium nitride-based layer containing chromium and nitrogen, and wherein, when a central region is defined on a surface of the pattern-forming thin film as an inner region of 1-μm square positioned with respect to a center of the substrate and an arithmetic mean roughness Sa and a maximum height Sz are measured in the central region, Sa is 1.0 nm or less and Sz/Sa is 14 or less. Thereby, it is possible to provide the mask blank having less microdefects on the surface of the pattern-forming thin film. Furthermore, the mask blank according to the present disclosure does not cause the above-mentioned problem that, when the defect inspection of the mask blank is performed by the most-advanced defect inspection apparatus, the inspection is terminated, for example, in the middle of the inspection (overflow).

In addition, by using the mask blank, it is possible to manufacture a transfer mask with a high-accuracy fine transfer pattern. Furthermore, by performing pattern transfer to a resist film on a semiconductor substrate using the transfer mask, it is possible to manufacture a high-quality semiconductor device with a device pattern excellent in pattern accuracy.

### BRIEF DESCRIPTION OF THE DRAWINGS

FIG. 1 is a schematic sectional view of a mask blank according to a first embodiment of the present disclosure;

FIG. 2 is a schematic sectional view of a specific configuration example of the mask blank according to the first embodiment of the present disclosure;

FIG. 3 is a schematic sectional view of another specific configuration example of the mask blank according to the first embodiment of the present disclosure;

FIG. 4 is a schematic sectional view of a mask blank according to a second embodiment of the present disclosure;

FIGS. 5A to 5E are schematic sectional views for describing a manufacturing process of a transfer mask using the mask blank according to the first embodiment of the present disclosure;

FIGS. 6A to 6E are schematic sectional views for describing a manufacturing process of a transfer mask using the mask blank according to the second embodiment of the present disclosure; and

FIG. 7 is a plan view for illustrating a central region and adjacent regions of the mask blank according to the present disclosure.

### Mode for Embodying the Disclosure

Now, modes for embodying the present disclosure will be described in detail with reference to the drawings.

First, a process leading to the present disclosure will be described.

In a mask blank having a light-shielding film of a chromium-based material formed on a substrate, in order to form the light-shielding film having a higher optical density (Optical Density: OD), a film containing chromium, oxygen, and carbon (CrOC film), for example, is formed by sputtering to a film thickness of, for example, 30 nm or more. In this event, a large number of microdefects may occur. In the present disclosure, the microdefect is a convex defect having a height of 10 nm or less and a size of 70 nm or less.

Due to presence of such microdefects on a surface of the light-shielding film, an adverse effect is possibly imposed on forming a fine pattern, as required in recent years, with high pattern accuracy. In addition, when defect inspection of a mask blank is performed by a most-advanced defect inspection apparatus using inspection light having a wavelength of 193 nm in recent years, there may arise a problem that, even if defects present on a surface of a pattern-forming thin film (light-shielding film) of the mask blank are microdefects, the inspection is terminated in the middle of the inspection (overflow) when the number of the defects is very large.

Therefore, the present inventors have studied about constituent elements in the film of the chromium-based material and, as a result, found out that the number of the microdefects mentioned above can be reduced by the chromium-based light-shielding film having a composition containing chromium and nitrogen. However, it has been found that the microdefects generated in the chromium-based light-shielding film are difficult to be suppressed only by specifying the constituent elements of the light-shielding film. It is necessary to suppress the growth of crystals generated in the light-shielding film by adjusting a film-forming condition when the light-shielding film is formed on the substrate by sputtering. However, the film-forming condition is highly dependent on a film forming apparatus to be used. For this reason, a new index is required to specify the film-forming condition unique to a sputtering apparatus, which is capable of suppressing the generation of the microdefects.

As a result of the study by the present inventors, it has been found out that, as a result of measuring the surface of the pattern-forming thin film (for example, the light-shielding film) of the mask blank by an atomic force microscope (Atomic Force Microscope: hereinafter abbreviated to “AFM”), there is a relatively large difference in numerical values of an arithmetic mean roughness Sa and a ratio of a maximum height Sz to the arithmetic mean roughness Sa (maximum height Sz/arithmetic mean roughness Sa) between a measurement location with the microdefects and a measurement location without any microdefects. In view of the above, the present inventors decided that it is suitable to use, as a parameter for defining presence or absence of the microdefects on the pattern-forming thin film of the mask blank, the numerical values of Sa and Sz/Sa calculated by performing AFM measurement on the pattern-forming thin film in a region of 1-μm square.

The present inventors comprehensively considered the above-mentioned findings and reached a conclusion that, in order to solve the above-mentioned problems, it is appropriate to provide a mask blank including a pattern-forming thin film on a substrate, wherein the pattern-forming thin film is a single-layer film containing chromium and nitrogen or a multi-layer film including a chromium nitride-based layer containing chromium and nitrogen, and wherein, when a central region is defined on a surface of the pattern-forming thin film as an inner region of 1-μm square positioned with respect to a center of the substrate and an arithmetic mean roughness Sa and a maximum height Sz are measured in the central region, Sa is 1.0 nm or less and Sz/Sa is 14 or less. Thus, the present disclosure has been completed.

Now, the present disclosure will be described in detail with reference to embodiments.

### Mask Blank

First, a mask blank according to the present disclosure will be described.

### First Embodiment

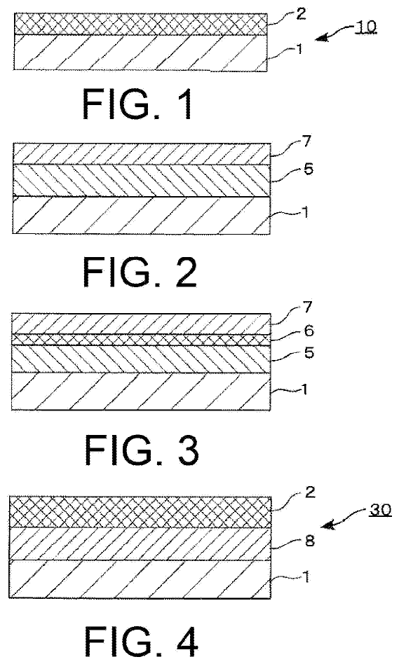

FIG. 1 is a schematic sectional view of a mask blank according to a first embodiment of the present disclosure.

As shown in FIG. 1, the mask blank 10 according to the first embodiment of the present disclosure is a mask blank having a structure including a pattern-forming thin film 2 formed on a substrate 1.

Herein, a transparent substrate is preferable as the substrate 1. As the transparent substrate, a glass substrate is typically cited. The glass substrate is excellent in flatness and smoothness. Therefore, when pattern transfer is performed to a targeted substrate using a transfer mask, high-accuracy pattern transfer can be performed without causing distortion or the like of a transfer pattern. The transparent substrate may be formed of a glass material such as synthetic quartz glass, quartz glass, aluminosilicate glass, soda lime glass, or low thermal expansion glass (SiO₂-TiO₂ glass or the like). Among those, synthetic quartz glass has a high transmittance to, for example, ArF excimer laser light (wavelength of 193 nm) as exposure light, and is particularly preferable as a material for forming the substrate 1 of the mask blank 10.

The pattern-forming thin film 2 is a single-layer film containing chromium and nitrogen or a multi-layer film including a chromium nitride-based layer containing chromium and nitrogen. The single-layer film containing chromium and nitrogen may have a film thickness of 30 nm or more, preferably 35 nm or more, further preferably 40 nm or more. The chromium nitride-based layer containing chromium and nitrogen may have a film thickness of 30 nm or more, preferably 35 nm or more, and further preferably 40 nm or more.

The pattern-forming thin film 2 is, for example, a light-shielding film in the case where it is the single-layer film containing chromium and nitrogen (hereinafter may be referred to as a “chromium nitride-based single-layer film”). As a specific material, CrN is preferable.

A content of nitrogen in a portion of the chromium nitride-based single-layer film, excluding a surface layer on the side opposite from the substrate 1, is preferably 8 atomic % or more, more preferably 10 atomic % or more, further preferably 12 atomic % or more. By containing 8 atomic % or more nitrogen, it is possible to suppress generation of microdefects on a surface of the pattern-forming thin film 2.

Herein, the surface layer of the chromium nitride-based single-layer film on the side opposite from the substrate 1 is excluded because the surface layer of the chromium nitride-based single-layer film is inevitably turned into chromium oxide when the chromium nitride-based single-layer film after formed by sputtering is subjected to treatment such as cleaning. The surface layer refers to a region extending from a surface of the chromium nitride-based single-layer film on the side opposite from the substrate 1 to a depth of 5 nm in a depth direction.

When the content of nitrogen in a chromium nitride-based material is large, there arises a problem that an optical density of the chromium nitride-based single-layer film with respect to the exposure light is reduced. Therefore, the content of nitrogen in the chromium nitride-based single-layer film is preferably 30 atomic % or less, more preferably 20 atomic % or less.

A content of chromium in the portion of the chromium nitride-based single-layer film excluding the surface layer on the side opposite from the substrate 1 is preferably 60 atomic % or more, more preferably 70 atomic % or more, further preferably 80 atomic % or more. The chromium nitride-based single-layer film is, for example, a light-shielding film and is required to ensure a predetermined optical density with respect to the exposure light. From such a viewpoint, the content of chromium is preferably 60 atomic % or more.

The chromium nitride-based single-layer film may be made of a material containing elements, such as oxygen and carbon, in addition to chromium and nitrogen (for example, CrOCN). From the above-mentioned viewpoint of suppressing the generation of microdefects on the surface of the pattern-forming thin film, a content of each element such as oxygen, carbon, boron, and hydrogen is preferably less than 5 atomic %, more preferably 3 atomic % or less. A total content of the elements such as oxygen, carbon, boron, and hydrogen is preferably 10 atomic % or less, more preferably 5 atomic % or less.

A thickness of the chromium nitride-based single-layer film may be 30 nm or more. The present disclosure can solve the problem in the existing technology that a large number of microdefects may occur, for example, when a CrOC film is formed by sputtering to a thickness of 30 nm or more in order to form a light-shielding film having a higher optical density (for example, an optical density of 3.3 or more with respect to exposure light of an ArF excimer laser (wavelength of 193 nm)).

In the case where the pattern-forming thin film 2 is a multi-layer film including a chromium nitride-based layer containing chromium and nitrogen, the multi-layer film is, for example, a light-shielding film. As a specific material of the chromium nitride-based layer, CrN is preferable.

A content of nitrogen in the chromium nitride-based layer of the multi-layer film is preferably 8 atomic % or more, more preferably 10 atomic % or more, further preferably 12 atomic % or more, as in the case of the chromium nitride-based single-layer film mentioned above. By containing 8 atomic % or more nitrogen, it is possible to suppress generation of microdefects on the surface of the pattern-forming thin film 2.

When the content of nitrogen in the chromium nitride-based material is large, there arises a problem that the optical density of the chromium nitride-based layer with respect to the exposure light is reduced. Therefore, the content of nitrogen in the chromium nitride-based layer is preferably 30 atomic % or less, more preferably 20 atomic % or less.

A content of chromium in the chromium nitride-based layer of the multi-layer film is preferably 60 atomic % or more, more preferably 70 atomic % or more, further preferably 80 atomic % or more, as in the case of the chromium nitride-based single-layer film. The chromium nitride-based layer is, for example, a main portion of the light-shielding film and is required to ensure a predetermined optical density with respect to the exposure light. From such a viewpoint, the content of chromium is preferably 60 atomic % or more.

As in the case of the chromium nitride-based single-layer film, the chromium nitride-based layer of the multi-layer film may be made of a material containing elements, such as oxygen and carbon, in addition to chromium and nitrogen (for example, CrOCN). From the above-mentioned viewpoint of suppressing the generation of microdefects on the surface of the pattern-forming thin film, a content of each element such as oxygen, carbon, boron, and hydrogen is preferably less than 5 atomic %, more preferably 3 atomic % or less. A total content of the elements such as oxygen, carbon, boron, and hydrogen is preferably 10 atomic % or less, more preferably 5 atomic % or less.

For example, a thickness of the chromium nitride-based layer of the multi-layer film, which is a main portion of the light-shielding film, may be 30 nm or more as in the case of the chromium nitride-based single-layer film mentioned above. The present disclosure can solve the problem in the existing technology that a large number of microdefects may occur, for example, when a CrOC film is formed by sputtering to a thickness of 30 nm or more in order to form a light-shielding film having a higher optical density (for example, an optical density of 3.3 or more with respect to exposure light of an ArF excimer laser (wavelength of 193 nm)).

In the mask blank 10 of the first embodiment, the pattern-forming thin film 2 may have a structure in which a hard mask layer containing silicon and oxygen is formed on the chromium nitride-based layer of the multi-layer film.

FIG. 2 is a schematic sectional view of a specific configuration example of the mask blank according to the first embodiment of the present disclosure. As shown in FIG. 2, the mask blank has a structure in which, as the pattern-forming thin film, a chromium nitride-based layer 5 and a hard mask layer 7 are sequentially stacked on the substrate 1.

Since the configuration of the chromium nitride-based layer 5 is the same as that described above, description thereof will be omitted herein.

The hard mask layer 7 functions as an etching mask when forming a transfer pattern on the chromium nitride-based layer 5. Therefore, the hard mask layer 7 is required to be a material having a high etching selectivity with respect to the chromium nitride-based layer 5 directly below the hard mask layer 7. In the first embodiment, a silicon-based material is selected as the material of the hard mask layer 7 so as to ensure the high etching selectivity with respect to the chromium nitride-based layer 5.

In the first embodiment, the hard mask layer 7 is made of a material containing silicon and oxygen. For example, a material (SiO-based material) comprising silicon and oxygen, or another material (SiNO-based material) containing an element such as nitrogen in addition to the above-mentioned material is preferable. On the other hand, the hard mask layer 7 may be formed of a material containing tantalum. The material containing tantalum in this case may be tantalum metal or a material containing tantalum and one or more elements selected from nitrogen, oxygen, boron, and carbon. For example, Ta, TaN, TaO, TaON, TaBN, TaBO, TaBON, TaCN, TaCO, TaCON, TaBCN, TaBOCN, and the like are cited.

A film thickness of the hard mask layer 7 need not particularly be limited. However, the hard mask layer 7 functions as an etching mask when patterning the chromium nitride-based layer 5 (light-shielding film) directly below the hard mask layer 7 by dry etching using a chlorine-based gas and, therefore, requires a film thickness enough not to disappear before completion of etching of the chromium nitride-based layer 5 directly below the hard mask layer 7. On the other hand, when the film thickness of the hard mask layer 7 is large, thinning of a resist pattern directly above the hard mask layer 7 is difficult. From such a viewpoint, the film thickness of the hard mask layer 7 is preferably in the range of, for example, 2 nm or more and 15 nm or less, more preferably 3 nm or more and 10 nm or less.

In the mask blank 10 of the first embodiment, the pattern-forming thin film 2 may have a structure in which an upper layer containing chromium, oxygen, and nitrogen is formed on the chromium nitride-based layer of the multi-layer film.

FIG. 3 is a schematic sectional view of another specific configuration example of the mask blank according to the first embodiment of the present disclosure. As shown in FIG. 3, the mask blank has a structure in which, as the pattern-forming thin film, the chromium nitride-based layer 5, an upper layer 6 of a chromium-based material, and the hard mask layer 7 are sequentially stacked on the substrate 1. In this configuration example, a layered structure of the chromium nitride-based layer 5 and the upper layer 6 made of the chromium-based material is provided as the light-shielding film.

Since the configuration of the chromium nitride-based layer 5 is the same as that described above, description thereof will be omitted herein.

In the first embodiment, the upper layer 6 is made of a material containing chromium, oxygen, and nitrogen. For example, a material (CrON-based material) consisting of chromium, oxygen, and nitrogen or another material (CrOCN-based material) further containing an element such as carbon in addition to the above-mentioned material is preferable. The upper layer 6 may contain another element such as carbon, boron, and hydrogen in addition to chromium, oxygen, and nitrogen.

A content of chromium in the upper layer 6 is preferably less than 60 atomic %, more preferably 55 atomic % or less. The content of chromium in the upper layer 6 is preferably 30 atomic % or more, more preferably 40 atomic % or more. A content of oxygen in the upper layer 6 is preferably 10 atomic % or more, more preferably 15 atomic % or more. The content of oxygen in the upper layer 6 is preferably 40 atomic % or less, more preferably 30 atomic % or less. A content of nitrogen in the upper layer 6 is preferably 5 atomic % or more, more preferably 7 atomic % or more. The content of nitrogen in the upper layer 6 is preferably 20 atomic % or less, more preferably 15 atomic % or less. A content of carbon in the upper layer 6 is preferably 5 atomic % or more, more preferably 7 atomic % or more. The content of carbon in the upper layer 6 is preferably 20 atomic % or less, more preferably 15 atomic % or less.

By providing the upper layer 6 made of the chromium-based material on the chromium nitride-based layer 5, a surface reflectance of the light-shielding film can be reduced (for example, the reflectance of less than 35% with respect to exposure light of an ArF excimer laser (wavelength of 193 nm)). From this viewpoint, the film thickness of the upper layer 6 is preferably in the range of, for example, 2 nm or more and 10 nm or less, more preferably 3 nm or more and 7 nm or less.

In the configuration example shown in FIG. 3, the hard mask layer 7 is provided on the upper layer 6 as described above. Since the configuration of the hard mask layer 7 is the same as that described above, description thereof is omitted herein.

The mask blank 10 of the first embodiment may be manufactured by forming the above-mentioned pattern-forming thin film 2 on the substrate 1. The pattern-forming thin film 2 is the chromium nitride-based single-layer film, a layered film (FIG. 2) including the chromium nitride-based layer 5 and the hard mask layer 7, or a layered film (FIG. 3) including the chromium-nitride based layer 5, the upper layer 6 made of the chromium-based material, and the hard mask layer 7.

A method of forming the pattern-forming thin film 2 need not particularly be limited. Especially, however, sputtering film formation is preferable. The sputtering film formation is advantageous because a uniform film with a constant film thickness can be formed.

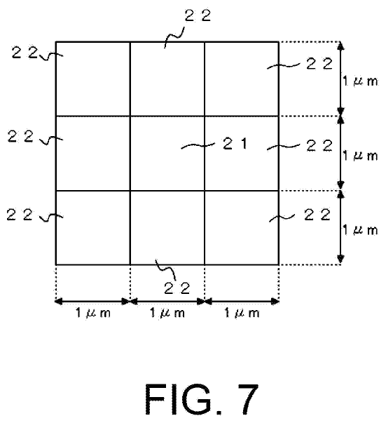

The mask blank 10 of the first embodiment is characterized in that, when a central region 21 (FIG. 7) is defined on a surface of the pattern-forming thin film 2 as an inner region of 1-μm square positioned with respect to a center of the substrate 1 and an arithmetic mean roughness Sa and a maximum height Sz are measured in the central region 21, Sa is 1.0 nm or less and Sz/Sa is 14 or less.

It is noted here that the arithmetic mean roughness Sa is a parameter defined by ISO 25178 to evaluate surface roughness, and is a parameter obtained by extending a line roughness parameter Ra (arithmetic mean height of a line), which represents a two-dimensional surface texture defined in ISO 4287 and JIS B0601, to three dimensions (plane). Specifically, the arithmetic mean roughness represents an average of absolute values of height differences (Z(x, y)) of measurement points in a reference region A from a mean surface (the least square plane or the like). A calculation formula is expressed as follows.

$$S a = \frac{1}{A} \int {\int }_{A} \vert Z ( x , y ) \vert dxdy \qquad [ Equation 1 ]$$

The maximum height Sz is a parameter obtained by extending a line roughness parameter Rz (maximum height) to three dimensions (plane), and is a sum of a maximum peak height Sp and a maximum valley depth Sv in the reference region A. That is, the maximum height Sz is expressed as follows.

Sz=Sp+Sv

Herein, the maximum peak height Sp and the maximum valley depth Sv are parameters obtained by extending the line roughness parameters Rp and Rv to three dimensions (plane), respectively. The maximum peak height Sp represents the maximum value of a height of a peak in the reference region A. The maximum valley depth Sv represents the maximum value of a depth of a valley in the reference region A.

These parameters Sz, Sp, Sv are also defined by ISO 25178.

In the present disclosure, the reference region A refers to the central region 21, which is defined on the surface of the pattern-forming thin film 2 as the inner region of 1-μm square positioned with respect to the center of the substrate 1, and adjacent regions 22 which will later be described (see FIG. 7).

In the present disclosure, numerical values of the arithmetic mean roughness Sa, the maximum height Sz, and Sz/Sa, which are calculated by AFM measurement performed in 1-μm square on the surface of the pattern-forming thin film 2, are used.

As described above, as a result of the study by the present inventors, it has been found out that, as a result of measuring the surface of the pattern-forming thin film (for example, the light-shielding film) of the mask blank by AFM, there is a relatively large difference in numerical values of the arithmetic mean roughness Sa and the ratio of the maximum height Sz to the arithmetic mean roughness Sa (maximum height Sz/arithmetic mean roughness Sa) between the measurement location with the microdefects and the measurement location without any microdefects. In view of the above, the present inventors decided that it is suitable to use, as a parameter for defining presence or absence of the microdefects on the pattern-forming thin film of the mask blank, the numerical values of the arithmetic mean roughness Sa and Sz/Sa calculated by performing AFM measurement on the pattern-forming thin film in a region of 1-μm square.

In the mask blank 10 of the first embodiment, when the central region 21 is defined on the surface of the pattern-forming thin film 2 as the inner region of 1-μm square positioned with respect to the center of the substrate 1 and the arithmetic mean roughness Sa and the maximum height Sz are measured in the central region 21, Sa is 1.0 nm or less and Sz/Sa is 14 or less. Thereby, the mask blank has less microdefects on the surface of the pattern-forming thin film. Particularly preferably, Sz/Sa is 12 or less. Particularly preferably, Sa is 0.6 or less.

Accordingly, there does not arise the above-mentioned problem that, when the defect inspection of the mask blank is performed by the most-advanced defect inspection apparatus using the inspection light having the wavelength of 193 nm, the inspection is terminated in the middle of the inspection (overflow), for example.

The present disclosure defines the numerical values of Sa and Sz/Sa when the central region 21 is defined on the surface of the pattern-forming thin film 2 as the inner region of 1-μm square positioned with respect to the center of the substrate 1 and the arithmetic mean roughness Sa and the maximum height Sz are measured in the central region 21. The study of the present inventors has given a knowledge that, if a large number of microdefects occur in a pattern-forming region (for example, the pattern-forming region is 132 nm×132 nm in a mask blank of a 6-inch square) of the pattern-forming thin film, it is highly probable that the microdefects are present also in the central region 21 of the pattern-forming thin film. Accordingly, there is a correlation between the number of microdefects being small in the central region 21 of the pattern-forming thin film and the number of microdefects at least in the pattern-forming region of the pattern-forming thin film being the number (for example, 100 or less) such that no adverse effect is given upon carrying out the defect inspection. From the foregoing, the present disclosure defines the numerical values of Sa and Sz/Sa when the measurement is performed in the central region 21.

In the case where microdefects occur in the chromium nitride-based single-layer film of the pattern-forming thin film 2, even if the hard mask layer 7 is formed thereon, microdefects occur on a surface of the hard mask layer 7 due to the microdefects in the chromium nitride-based single-layer film. Furthermore, in the case where the microdefects occur in the chromium nitride-based single-layer film of the pattern-forming thin film 2, even if the upper layer 6 and the hard mask layer 7 are formed thereon, defects occur on surfaces of the upper layer 6 and the hard mask layer 7 due to the microdefects in the chromium nitride-based single-layer film. Therefore, it is possible to use, as indexes for evaluating the microdefects on the surface of the chromium nitride-based single-layer film or the chromium nitride-based layer 5, Sa and Sz/Sa which are calculated by performing AFM measurement in a region of 1-μm square on the surface of the upper layer 6 or the hard mask layer 7 as an uppermost layer of the pattern-forming thin film 2.

As shown in FIG. 7, in the present disclosure, it is more preferable that, when the eight adjacent regions 22, each being an inner region of 1-μm square, are defined on the surface of the pattern-forming thin film 2 to surround the central region 21 in contact with its outer periphery (including four sides and four corners) and the arithmetic mean roughness Sa and the maximum height Sz are measured in all of the adjacent regions 22, all values of Sa are 1.0 nm or less and all values of Sz/Sa are 14 or less. Furthermore, all values of Sz/Sa are particularly preferably 12 or less and all values of Sa are particularly preferably 0.6 or less. Each of the eight adjacent regions 22 does not have a region overlapping the other adjacent regions. The periphery of the central region 21 is entirely surrounded by the eight adjacent regions 22. That is, one side of each of the four adjacent regions 22 among the eight adjacent regions 22 correspond to each of the four sides of the central region 21. Furthermore, one corner of each of the other four adjacent regions is in contact with each of the four corners of the central region 21. Each of the adjacent regions 22 has two sides each corresponding to one side of each of the two other adjacent regions 22 adjacent thereto, except the one side corresponding to one side of the central region 21.

By providing the mask blank in which all values of Sa are 1.0 nm or less and all values of Sz/Sa are 14 or less in the adjacent regions 22 also, reliability related to few microdefects being present on the surface of the pattern-forming thin film is further enhanced.

In the present disclosure, the maximum height Sz of the central region 21 is preferably 10 nm or less. By providing the mask blank in which Sz/Sa is 14 or less and the maximum height Sz is 10 nm or less when measured in the central region 21, reliability related to few microdefects being present on the surface of the pattern-forming thin film is further enhanced. Furthermore, in all of the adjacent regions 22 also, the maximum height Sz is more preferably 10 nm or less.

In the present disclosure, root mean square roughness Sq of the central region 21 is preferably 1.0 nm or less. Herein, the root mean square roughness Sq is a parameter defined by ISO 25178 to evaluate surface roughness, like the arithmetic mean roughness Sa and the maximum height Sz, and is a parameter obtained by extending a line roughness parameter Rq (root mean square roughness of a line), which represents a two-dimensional surface texture defined in ISO 4287 and JIS B0601, to three dimensions (plane). A calculation formula of Sq is expressed as follows.

$$S q = \sqrt{\frac{1}{A} \int {\int }_{A} {z}^{2} ( x , y ) dxdy}$$

With the root mean square roughness Sq of the central region 21 being 1.0 nm or less, LER (Line Edge Roughness) of a pattern sidewall when the pattern-forming thin film is patterned becomes more excellent. More preferably, the root mean square roughness Sq is 0.8 nm or less. Furthermore, in all of the adjacent regions 22 also, the root mean square roughness Sq is preferably 1.0 nm or less, more preferably 0.8 nm or less.

In the mask blank 10 of the first embodiment, when the surface of the pattern-forming thin film 2 is subjected to defect inspection by a defect inspection apparatus using inspection light having a wavelength of 193 nm to obtain distribution of convex defects in a pattern-forming region which is an inner region of 132-mm square, microdefects being the convex defects having a height of 10 nm or less are present in the pattern-forming region and the number of the microdefects present in the pattern-forming region is 100 or less. That is, the number of the microdefects at least in the pattern-forming region of the pattern-forming thin film 2 is the number such that no adverse effect is given upon carrying out the defect inspection.

Specifically, for example, the surface of the pattern-forming thin film (a light-shielding film or a hard mask film) of the mask blank is subjected to defect inspection by the defect inspection apparatus using inspection light having a wavelength of 193 nm as described above to obtain a coordinate map of defects. For all locations where the defects are present (except those defects which are obviously foreign matter defects and concave defects known in the art), the heights of the defects may be measured by AFM to count the number of the microdefects.

### Second Embodiment

FIG. 4 is a schematic sectional view showing a mask blank according to a second embodiment of the present disclosure. As shown in FIG. 4, the mask blank 30 according to the second embodiment of the present disclosure is a mask blank having a structure including a phase shift film 8 between the substrate 1 and the pattern-forming thin film 2.

For example, the phase shift film 8 is a film having a function of transmitting exposure light of an ArF excimer laser (wavelength of 193 nm) at a transmittance of 8% or more, and a function of generating a phase difference of 150 degrees or more and 210 degrees or less between the exposure light transmitted through the phase shift film 8 and the exposure light passing through air by the same distance as the thickness of the phase shift film 8. The mask blank 30 with the phase shift film 8 having those functions is a mask blank for manufacturing a halftone phase shift mask. The light shielding film formed on the phase shift film having a relatively high transmittance of 8% or more is required to have a high optical density with respect to the exposure light. Therefore, a large effect is obtained by using the chromium nitride-based single-layer film or the chromium nitride-based layer 5 (FIG. 2, FIG. 3) as the pattern-forming thin film 2.

In the mask blank 30 of the second embodiment, the phase shift film 8 is formed of, for example, a silicon-containing material. However, the configuration of the phase shift film 8 used in the second embodiment is not particularly limited. For example, configurations of phase shift films in conventional phase shift masks are applicable.

The phase shift film 8 is formed of, for example, a silicon-containing material, a material containing transition metal and silicon, or a material further containing at least one element selected from nitrogen, oxygen and carbon in addition to either the silicon-containing material or the material containing transition metal and silicon in order to improve optical characteristics (such as light transmittance, phase difference, etc.), physical properties (etching rate, etching selectivity with respect to another film (layer)), and so on.

Specifically, as the silicon-containing material, a material containing nitride, oxide, carbide, oxynitride (oxide nitride), carbonate (carbide oxide), or carbonate nitride (carbide oxide nitride) of silicon is preferable.

Specifically, as the material containing transition metal and silicon, a material containing transition metal silicide consisting of transition metal and silicon, or nitride, oxide, carbide, oxynitride, carbonate, or carbonate nitride of transition metal silicide is preferable. As transition metal, molybdenum, tantalum, tungsten, titanium, chromium, hafnium, nickel, vanadium, zirconium, ruthenium, rhodium, niobium, or the like is applicable. Among those, molybdenum is particularly preferable.

The phase shift film 8 may be applied to either of a single-layer structure and a layered structure including a low-transmittance layer and a high-transmittance layer.

A preferable film thickness of the phase shift film 8 varies depending on the material, but is expected to be appropriately adjusted particularly from the viewpoint of a phase shift function and an exposure light transmittance. A typical film thickness is, for example, within a range of 100 nm or less, more preferably 80 nm or less. Although a method of forming the phase shift film 8 is not particularly limited, a sputtering film forming method is preferable.

Details of the substrate 1 and the pattern-forming thin film 2 in the mask blank 30 of the second embodiment are the same as those in the first embodiment described above. Therefore, repetitive description is omitted herein.

As a method of forming the pattern-forming thin film 2 in the mask blank 30 of the second embodiment, the sputtering film forming method is suitable as in the first embodiment. Also, the film thickness of the chromium nitride-based single-layer film forming the pattern-forming thin film 2 or the film thickness of each film in the layered film, including the chromium nitride-based layer 5, the upper layer 6 made of a chromium-based material, and the hard mask layer 7, described in conjunction with FIGS. 2 and 3, is the same as that in the first embodiment.

In the mask blank 30 of the second embodiment, in the layered structure of the phase shift film 8 and the pattern-forming thin film 2, the optical density (OD) with respect to, for example, exposure light of an ArF excimer laser (wavelength of 193 nm) is preferably 3.3 or more.

The mask blank 30 of the second embodiment is also characterized in that, when the central region 21 is defined on the surface of the pattern-forming thin film 2 as the inner region of 1-μm square positioned with respect to the center of the substrate 1 and the arithmetic mean roughness Sa and the maximum height Sz are measured in the central region 21, Sa is 1.0 nm or less and Sz/Sa is 14 or less.

In the mask blank 30 of the second embodiment, when the central region 21 is defined on the surface of the pattern-forming thin film 2 as the inner region of 1-μm square positioned with respect to the center of the substrate 1 and the arithmetic mean roughness Sa and the maximum height Sz are measured in the central region 21, Sa is 1.0 nm or less and Sz/Sa is 14 or less. Thereby, the mask blank has less microdefects on the surface of the pattern-forming thin film. Sz/Sa is particularly preferably 12 or less, and Sa is particularly preferably 0.6 nm or less.

In the second embodiment also, when eight adjacent regions 22, each being an inner region of 1-μm square, are defined on the surface of the pattern-forming thin film 2 in contact with the outer periphery of the central region 21 and the arithmetic mean roughness Sa and the maximum height Sz are measured in all of the adjacent regions 22, it is more preferable that all values of Sa are 1.0 nm or less and that all values of Sz/Sa are 14 or less. Furthermore, all values of Sz/Sa are particularly preferably 12 or less and all values of Sa are particularly preferably 0.6 nm or less.

By providing the mask blank in which all values of Sa are 1.0 nm or less and all values of Sz/Sa are 14 or less in the eight adjacent regions 22 also, reliability related to few microdefects being present on the surface of the pattern-forming thin film is further enhanced.

In the second embodiment also, the maximum height Sz of the central region 21 is preferably 10 nm or less. By providing the mask blank in which Sz/Sa is 14 or less and the maximum height Sz is 10 nm or less when measured in the central region 21, reliability related to few microdefects being present on the surface of the pattern-forming thin film is further enhanced. Furthermore, in all of the adjacent regions 22 also, the maximum height Sz is more preferably 10 nm or less.

In the second embodiment also, the root-mean-square roughness Sq of the central region 21 is preferably 1.0 nm or less. With the root-mean-square roughness Sq of the central region 21 being 1.0 nm or less, the LER (Line Edge Roughness) of the pattern sidewall when the pattern-forming thin film is patterned becomes a more favorable value. The root-mean-square roughness Sq of the central region 21 is more preferably 0.8 nm or less. Furthermore, in all of the adjacent regions 22 also, the root-mean-square roughness Sq is preferably 1.0 nm or less, more preferably 0.8 nm or less.

With respect to the mask blank 30 of the second embodiment also, when the surface of the pattern-forming thin film 2 is subjected to defect inspection by a defect inspection apparatus using inspection light having a wavelength of 193 nm to obtain distribution of convex defects in a pattern-forming region which is an inner region of 132-mm square, microdefects being the convex defects having a height of 10 nm or less are present in the pattern-forming region and the number of the microdefects present in the pattern-forming region is 100 or less. Thus, the number of the microdefects at least in the pattern-forming region of the pattern-forming thin film 2 is the number that does not adversely affect the defect inspection.

### Method for Manufacturing Transfer Mask

The present disclosure also provides a method for manufacturing a transfer mask manufactured from the above-mentioned mask blank according to the present disclosure.

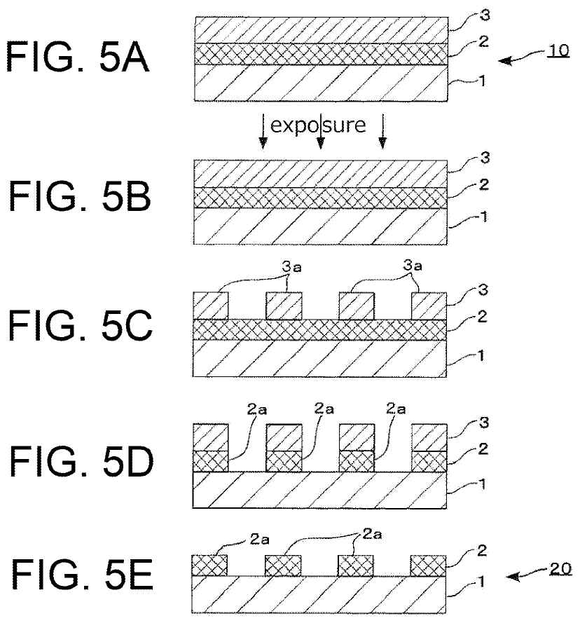

FIGS. 5A to 5E are schematic sectional views showing a manufacturing process of the transfer mask using the mask blank 10 according to the first embodiment described above. The method for manufacturing the transfer mask according to the present disclosure at least includes a step of forming a transfer pattern on the pattern-forming thin film 2 by dry etching with a resist film having a transfer pattern used as a mask.

In the method for manufacturing the transfer mask according to the present disclosure, at first, a resist film 3 for electron beam writing is formed on a surface of the mask blank 10 to a predetermined film thickness, for example, by spin coating. On the resist film, a predetermined pattern is formed by electron beam writing and, after the writing, developed to thereby form a predetermined resist film pattern 3a (see FIGS. 5A to 5C). The resist film pattern 3a has a desired device pattern to become a final transfer pattern.

Next, by dry etching using a gas mixture of a chlorine-based gas and oxygen gas with the resist film pattern 3a used as a mask, a transfer pattern 2a is formed on the pattern-forming thin film 2 (light-shielding film), whose main portion is made of a chromium-based material (see FIG. 5D).

The remaining resist film pattern 3a is removed to complete a binary transfer mask 20 in which a fine pattern of the pattern-forming thin film (light-shielding film) to serve as the transfer pattern 2a is formed on the substrate 1 (see FIG. 5E).

Thus, by using the mask blank 10 with few microdefects on the surface of the pattern-forming thin film, it is possible to manufacture the transfer mask 20 provided with a high-accuracy fine transfer pattern.

In the case where the pattern-forming thin film 2 is provided with the above-mentioned hard mask layer 7 of the silicon-based material, the method includes a step of forming a transfer pattern on the hard mask layer 7 by dry etching using a fluorine-based gas with the resist film pattern 3a used as a mask. Then, by dry etching with the hard mask layer 7 having the transfer pattern used as a mask, a transfer pattern is formed on the chromium-based light shielding film, made of the chromium-based material, in the pattern-forming thin film.

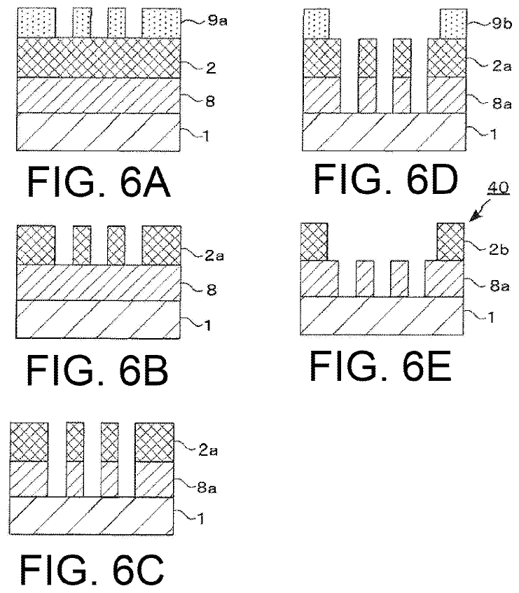

FIGS. 6A to 6E are schematic sectional views showing a manufacturing process of a transfer mask using the mask blank 30 according to the second embodiment, A method for manufacturing the transfer mask using the mask blank 30 at least includes a step of forming a transfer pattern on the pattern-forming thin film 2 by dry etching with a resist film having a transfer pattern used as a mask, and a step of forming on the phase shift film 8 by dry etching with the pattern-forming thin film 2 having the transfer pattern used as a mask.

In the method for manufacturing the transfer mask, at first, the resist film for electron beam writing is formed on a surface of the mask blank 30 to a predetermined film thickness, for example, by spin coating. On the resist film, a predetermined pattern is formed by electron beam writing and, after the writing, developed to form a predetermined resist film pattern 9a (see FIG. 6A). The resist film pattern 9a has a desired device pattern to be formed on the phase shift film 8 and to become a final transfer pattern.

Next, by dry etching using a gas mixture of a chlorine-based gas and oxygen gas with the resist film pattern 9a used as a mask, the transfer pattern 2a is formed on the pattern-forming thin film 2 (light-shielding film), whose main portion is made of a chromium-based material (see FIG. 6B).

Next, by dry etching using a fluorine-based gas and using, as a mask, the transfer pattern 2a formed on the pattern-forming thin film 2, a transfer pattern 8a is formed on the phase shift film 8 of a silicon-based material (see FIG. 6C).

Next, a resist film similar to that described above is formed on an entire surface of the mask blank provided with the transfer pattern 2a and the transfer pattern 8a. On the resist film, a predetermined light-shielding pattern (for example, a light shielding zone pattern) is formed by writing and, after the writing, developed to form, on the transfer pattern 2a, a resist film pattern 9b having a predetermined light-shielding pattern (see FIG. 6D).

Next, by dry etching using a gas mixture of a chlorine-based gas and oxygen gas with the resist pattern 9b used as a mask, a pattern 2b having the light-shielding pattern is formed on the pattern-forming thin film 2 (see FIG. 6E).

In the above-mentioned manner, a halftone phase shift mask (transfer mask) 40 is completed in which the fine pattern 8a of the phase shift film 8 to serve as a transfer pattern is formed on the substrate 1 and the light-shielding pattern (light-shielding zone pattern) 2b is formed in an outer peripheral region (see FIG. 6E).

In the above-described manufacturing process also, in the case where the above-mentioned hard mask layer 7 of the silicon-based material is formed on the pattern-forming thin film 2, the method includes a step of forming a transfer pattern on the hard mask layer 7 by dry etching using a fluorine-based gas with the resist film pattern 9a used as a mask. Then, by dry etching with the hard mask layer 7 having the transfer pattern used as a mask, the transfer pattern 2a is formed on the chromium-based light-shielding film in the pattern-forming thin film made of the chromium-based material.

Thus, by using the mask blank 30 with few microdefects on the surface of the pattern-forming thin film, it is possible to manufacture the transfer mask (halftone phase shift mask) 40 provided with a high-accuracy fine transfer pattern.

### Method for Manufacturing Semiconductor Device

The present disclosure also provides a method for manufacturing a semiconductor device, which includes a step of carrying out exposure transfer of a transfer pattern to a resist film on a semiconductor substrate by using the transfer mask manufactured by the above-described method for manufacturing the transfer mask.

The method for manufacturing the semiconductor device according to the present disclosure includes a step of using, for example, the transfer mask 20 manufactured from the mask blank 10 of the first embodiment or the transfer mask 40 manufactured from the mask blank 30 of the second embodiment and carrying out exposure transfer of the transfer pattern of the transfer mask to the resist film on the semiconductor substrate by lithography. According to the method for manufacturing the semiconductor device, it is possible to manufacture a high-quality semiconductor device provided with a device pattern excellent in pattern accuracy.

### EXAMPLES

Hereinafter, the embodiments of the present disclosure will be described more in detail with reference to examples.

### Example 1

Example 1 relates to the mask blank 30 for use in manufacturing a transfer mask with an ArF excimer laser having a wavelength of 193 nm used as exposure light.

The mask blank 30 used in Example 1 has a structure in which the phase shift film 8 and, as the pattern-forming thin film 2, a chromium nitride-based layer 5, an upper layer 6 made of a chromium-based material, and a hard mask layer 7 are stacked in this order on the transparent substrate 1 (see FIGS. 4 and 3 mentioned above; the reference numerals correspond to those in the figures). In Example 1, the light-shielding film is formed by a stack of the chromium nitride-based layer 5 and the upper layer 6 made of the chromium-based material.

The mask blank 30 was manufactured in the following manner.

The transparent substrate 1 made of synthetic quartz glass (having a size of about 152 mm×152 mm and a thickness of about 6.35 mm) was prepared. In the transparent substrate 1, a main surface and end surfaces were polished to a predetermined surface roughness (for example, 0.2 nm or less in root mean square roughness Rq for the main surface).

First, the transparent substrate 1 was placed in a single-wafer DC sputtering apparatus. Using a mixed target of molybdenum (Mo) and silicon (Si) (Mo:Si=8 atomic %:92 atomic %) with a gas mixture of argon (Ar), oxygen (O₂), nitrogen (N₂), and helium (He) used as a sputtering gas, DC sputtering was carried out to form the phase shift film 8 made of an MoSiON film containing molybdenum, silicon ; oxygen, and nitrogen (Mo: 10 atomic %, Si: 45 atomic %, O: 5 atomic %, N: 40 atomic %) on the surface of the transparent substrate 1 to a thickness of 68 nm.

Next, the transparent substrate 1 with the phase shift film 8 formed thereon was taken out from the sputtering apparatus, and the phase shift film 8 on the transparent substrate was subjected to heat treatment in the atmosphere. The heat treatment was carried out at 450° C. for 30 minutes. For the phase shift film 8 after the heat treatment, a transmittance and a phase shift amount at the wavelength (193 nm) of the ArF excimer laser were measured by using a phase shift measuring apparatus. As a result, the transmittance was 8.9% and the phase shift amount was 175.2 degrees.

Next, the transparent substrate 1 with the phase shift film 8 formed thereon was introduced again into the sputtering apparatus. Using a target of chromium and a gas mixture of argon (Ar), nitrogen (N₂), and helium (He) (flow rate ratio Ar:N₂:He=15:10:30, pressure of 0.2 Pa) as a sputtering gas, DC sputtering was carried out to form, on the phase shift film 8, the chromium nitride-based layer 5 made of a CrN film containing chromium and nitrogen (Cr: 86 atomic %, N: 14 atomic %) to a thickness of 43 nm. Subsequently, using the chromium target same as that mentioned above and a gas mixture of argon (Ar), carbon dioxide (CO₂), nitrogen (N₂), and helium (He) (flow rate ratio Ar:CO₂:N₂:He=16:30:10:30, pressure of 0.2 Pa) as a sputtering gas, DC sputtering was carried out to form the upper layer 6 of the light-shielding film on the chromium nitride-based layer 5 to a thickness of 6 nm, the upper layer 6 being made of a CrOCN film containing chromium, oxygen, carbon, and nitrogen (Cr: 55 atomic %, O: 24 atomic %, C: 11 atomic %, N: 10 atomic %). Thus, a chromium-based light-shielding film of a two-layer structure having a total thickness of 49 nm was formed.

A stacked structure of the phase shift film 8 and the light-shielding film (the stack of the chromium nitride-based layer 5 and the upper layer 6) had the optical density of 3.5 with respect to the exposure light of the ArF excimer laser (wavelength of 193 nm).

Next, the transparent substrate 1 with those films through the light-shielding film formed thereon was placed in the single-wafer DC sputtering apparatus. Using a target of silicon (Si) and a gas mixture of argon (Ar), oxygen (O₂), and nitrogen (N₂) as a sputtering gas, DC sputtering was carried out to form, on the upper layer 6, the hard mask layer 7 made of an SiON film containing silicon, oxygen, and nitrogen (Si: 34 atomic %, O: 60 atomic %, N: 6 atomic %) to a thickness of 8 nm.

As described above, the mask blank 30 in Example 1 was manufactured.

On a surface of the mask blank 30 in Example 1, that is, a surface of the hard mask layer 7, the central region 21 was defined as an inner region of 1-μm square positioned with respect to the center of the substrate 1. In the central region 21, AFM measurement was performed. From a measurement result, the arithmetic mean roughness Sa, the maximum height Sz, and the value of Sz/Sa were calculated. As a result, in the mask blank of Example 1, Sa=0.594 nm, Sz=6.71 nm, and Sz/Sa=11.30. The root mean square roughness Sq in the central region 21 was 0.75 nm.

On the surface of the hard mask layer 7 of the mask blank 30 in Example 1, eight adjacent regions 22, each being an inner region of 1-μm square, was defined so as to be in contact with the outer periphery of the central region 21. In the adjacent regions 22, AFM measurement was performed to measure the arithmetic mean roughness Sa and the maximum height Sz in all of the adjacent regions 22. As a result, it was confirmed that Sa was 1.0 nm or less and all values of Sz/Sa were 14 or less in all of the adjacent regions 22.

Furthermore, the surface of the mask blank 30 in Example 1 was subjected to defect inspection by a defect inspection apparatus Teron (manufactured by KLA) using inspection light having a wavelength of 193 nm to obtain a defect distribution (a defect coordinate map) in a pattern-forming region as an inner region of 132-mm square. Then, for all locations where defects were present (except obviously foreign matter defects and concave defects), the heights of the defects were measured by AFM and the number of microdefects being convex defects having a height of 10 nm or less and present in the pattern-forming region was counted. As a result, the number of the microdefects present in the pattern-forming region was two in the mask blank 30 in Example 1.

From the above, it has been found out that the mask blank 30 in Example 1 is a mask blank with few microdefects on its surface due to the arithmetic mean roughness Sa being 1.0 nm or less and Sz/Sa being 14 or less in the central region 21.

Next, using the mask blank 30, a transfer mask was manufactured according to the manufacturing process shown in FIGS. 6A to 6E.

First, a chemically amplified resist (PRL009 manufactured by Fuji Film Electronics Material Co. Ltd.) for electron beam writing was applied to an upper surface of the mask blank 30 by spin coating, and a predetermined baking treatment was performed to form a resist film having a film thickness of 80 nm. Next, using an electron beam writer, a predetermined device pattern (a pattern corresponding to a transfer pattern to be formed on the phase shift film 8) was written on the resist film and thereafter the resist film was developed to form a resist pattern 9a.

Next, by dry etching using a fluorine-based gas with the resist film pattern 9a used as a mask, a transfer pattern was formed on the hard mask layer 7

Next, after removing the remaining resist film pattern 9a, by dry etching using a gas mixture of a chlorine gas (Cl₂) and oxygen gas (O₂) (Cl₂:O₂=13:1 (flow rate ratio)) with the transfer pattern formed on the hard mask layer 7 used as a mask, the light-shielding film of a two-layer structure including CrN (chromium nitride-based layer 5) and CrOCN (upper layer 6) was continuously dry-etched to form a transfer pattern on the light-shielding film.

Next, by dry etching using a fluorine-based gas (SF₆) with the transfer pattern formed on the light-shielding film of the two-layer structure used as a mask, a transfer pattern (phase shift film pattern 8a) was formed on the phase shift film 8.

Next, a resist film which was the same as that described above was formed on an entire surface of the mask blank provided with the pattern of the light-shielding film and the pattern of the phase shift film. On the resist film, a predetermined light-shielding pattern (light-shielding zone pattern) was written and, after the writing, developed so that the resist film pattern 9b having a predetermined light-shielding pattern was formed on the pattern of the light-shielding film.

Next, by dry etching using a gas mixture of a chlorine-based gas and oxygen gas with the resist pattern 9b used as a mask, a pattern (corresponding to the pattern 2b in FIG. 6E) having the light-shielding pattern was formed on the light-shielding film of the two-layer structure.

As described above, a halftone phase shift mask (transfer mask) 40 was completed in which the pattern 8a of the phase shift film to serve as a transfer pattern and the light-shielding pattern (light-shielding zone pattern) in the outer peripheral region were formed on the transparent substrate 1 (see FIG. 6E),

The phase shift mask 40 thus obtained was subjected to mask pattern inspection by a mask inspection apparatus. As a result, it was confirmed that the fine pattern of the phase shift film was formed within an allowable range from a designed value.

Furthermore, using AIMS 193 (manufactured by Carl Zeiss Co. Ltd.), the phase shift mask 40 was subjected to simulation of an exposure transfer image obtained by assuming exposure transfer to a resist film on a semiconductor device was carried out by exposure light having a wavelength of 193 nm. As a result of checking the exposure transfer image obtained by this simulation, design specification was sufficiently satisfied. Therefore, the phase shift mask 40 manufactured from the mask blank 30 of Example 1 is capable of performing exposure transfer with high accuracy to the resist film on the semiconductor device.

### Example 2

Example 2 relates to the mask blank 30 for use in manufacturing a transfer mask with an ArF excimer laser having a wavelength of 193 nm used as exposure light.

The mask blank 30 used in Example 2 has a structure in which the phase shift film 8 and, as the pattern-forming thin film 2, the chromium nitride-based layer 5 and the hard mask layer 7 are stacked in this order on the transparent substrate 1 (see FIGS. 4 and 2 mentioned above; the reference numerals correspond to those in the figures). In Example 2, the light-shielding film is formed by the chromium nitride-based layer 5 as a single layer.

The mask blank 30 was manufactured in the following manner.

First, the transparent substrate 1 (synthetic quartz substrate) prepared in the same manner as that of Example 1 was placed in a single-wafer DC sputtering apparatus, and the phase shift film 8 same as that in Example 1 was formed.

Next, the transparent substrate 1 with the phase shift film 8 formed thereon was introduced again into the sputtering apparatus. Using a target of chromium and a gas mixture of argon (Ar), nitrogen (N₂), and helium (He) (flow rate ratio Ar:N₂:He=30:5:50, pressure of 0.3 Pa) as a sputtering gas, DC sputtering was carried out to form, on the phase shift film 8, the chromium nitride-based layer 5 made of a CrN film containing chromium and nitrogen (Cr: 94 atomic %, N: 6 atomic %) to a thickness of 48 nm. Thus, the chromium-based light-shielding film as a single layer was formed.

A stacked structure of the phase shift film 8 and the light-shielding film (the chromium nitride-based layer 5) had the optical density of 3.6 with respect to the exposure light of the ArF excimer laser (wavelength of 193 nm).

Next, the transparent substrate 1 with those films through the light-shielding film formed thereon was placed in the single-wafer DC sputtering apparatus. In the manner same as that of Example 1, the hard mask layer 7 made of the SiON film was formed.

As described above, the mask blank 30 in Example 2 was manufactured.

On the surface of the mask blank 30 in Example 2, that is, the surface of the hard mask layer 7, the central region 21 was defined as an inner region of 1-μm square positioned with respect to the center of the transparent substrate 1. In the central region 21, AFM measurement was performed. From a measurement result, the arithmetic mean roughness Sa, the maximum height Sz, and the value of Sz/Sa were calculated. As a result, in the mask blank of Example 2, Sa=0.462 nm, Sz=6.22 nm, Sz/Sa=13.46. The root mean square roughness Sq in the central region 21 was 0.592 nm.

On the surface of the hard mask layer 7 of the mask blank 30 in Example 2, eight adjacent regions 22, each being an inner region of 1-μm square, was defined so as to be in contact with the outer periphery of the central region 21. In the adjacent regions 22, AFM measurement was performed to measure the arithmetic mean roughness Sa and the maximum height Sz in all of the adjacent regions 22. As a result, it was confirmed that Sa was 1.0 nm or less and all values of Sz/Sa were 14 or less in all of the adjacent regions 22.

Furthermore, the surface of the mask blank 30 in Example 2 was subjected to defect inspection by the defect inspection apparatus Teron (manufactured by KLA) using inspection light having a wavelength of 193 nm to obtain a convex defect distribution (a defect coordinate map) in a pattern-forming region as an inner region of 132-mm square. Then, for all locations where defects were present (except obviously foreign matter defects and concave defects), the heights of the defects were measured by AFM and the number of microdefects being convex defects having a height of 10 nm or less and present in the pattern-forming region was counted. As a result, the number of microdefects present in the pattern-forming region was 72 in the mask blank 30 in Example 2.

From the above, it has been found out that the mask blank 30 in Example 2 is a mask blank with few microdefects on its surface due to Sa being 1.0 nm or less and Sz/Sa being 14 or less in the central region 21.

Considering the results in the above-mentioned Example 1 in combination, it has been found out that, due to the arithmetic mean roughness Sa being 1.0 nm or less and all values of the Sz/Sa being 14 or less in the central region 21 of the pattern-forming thin film of the mask blank, it is possible to assure that the mask blank has few microdefects (the number such that no adverse effect is given upon carrying out the defect inspection, for example, 100 or less) in at least the pattern-forming region of the pattern-forming thin film.

Next, using the mask blank 30, a transfer mask was manufactured according to a process similar to that in Example 1.

First, a chemically amplified resist (PRL009 manufactured by Fuji Film Electronics Material Co. Ltd,) for electron beam writing was applied to an upper surface of the mask blank 30 by spin coating, and a predetermined baking treatment was performed to form a resist film having a film thickness of 80 nm, Next, using an electron beam writer, a predetermined device pattern (a pattern corresponding to a transfer pattern to be formed on the phase shift film 8) was written on the resist film and thereafter the resist film was developed to form a resist pattern 9a.

Next, by dry etching using a fluorine-based gas with the resist film pattern 9a used as a mask, a transfer pattern was formed on the hard mask layer 7.

Next, after removing the remaining resist film pattern 9a, by dry etching using a gas mixture of a chlorine gas (Cl₂) and oxygen gas (O₂) (Cl₂:O₂=13:1 (flow rate ratio)) with the transfer pattern formed on the hard mask layer 7 used as a mask, the light-shielding film of a CrN film (chromium nitride-based layer 5) was dry-etched to form a transfer pattern on the light-shielding film.

Next, by dry etching using a fluorine-based gas (SF₆) with the transfer pattern formed on the CrN light-shielding film used as a mask, a transfer pattern (phase shift film pattern 8a) was formed on the phase shift film 8.

Next, a resist film which was the same as that described above was formed on an entire surface of the mask blank provided with the pattern of the light-shielding film and the pattern of the phase shift film. On the resist film, a predetermined light-shielding pattern (light-shielding zone pattern) was written and, after the writing, developed so that the resist film pattern 9b having a predetermined light-shielding pattern was formed on the pattern of the light-shielding film.

Next, by dry etching using a gas mixture of a chlorine-based gas and oxygen gas with the resist pattern 9b used as a mask, a pattern (corresponding to the pattern 2b in FIG. 6E) having the light-shielding pattern was formed on the CrN light-shielding film.

As described above, a halftone phase shift mask (transfer mask) 40 was completed in which the pattern 8a of the phase shift film to serve as a transfer pattern and the light-shielding pattern (light-shielding zone pattern) in the outer peripheral region were formed on the transparent substrate 1 (see FIG. 6E).

The phase shift mask 40 in Example 2 thus obtained was subjected to mask pattern inspection by a mask inspection apparatus. As a result, it was confirmed that the fine pattern of the phase shift film was formed within an allowable range from a design value.

Furthermore, using AIMS 193 (manufactured by Carl Zeiss Co. Ltd.), the phase shift mask 40 was subjected to simulation of an exposure transfer image obtained by assuming exposure transfer to a resist film on a semiconductor device was carried out by exposure light having a wavelength of 193 nm. As a result of checking the exposure transfer image obtained by this simulation, design specification was sufficiently satisfied. Therefore, the phase shift mask 40 manufactured from the mask blank 30 of Example 2 is capable of performing exposure transfer with high accuracy to the resist film on the semiconductor device.

### Comparative Example 1

A mask blank of Comparative Example 1 was prepared in the manner similar to Example 1 except that the light-shielding film was a CrOC single-layer film. That is, the mask blank of Comparative Example 1 has a structure in which a phase shift film, a light-shielding film made of a CrOC film, and a hard mask layer are stacked in this order on a transparent substrate.

The mask blank of Comparative Example 1 was manufactured in the following manner.

First, the transparent substrate (synthetic quartz substrate) prepared in the same manner as that of Example 1 was placed in a single-wafer DC sputtering apparatus, and a phase shift film which was the same as that in Example 1 was formed.

Next, the substrate with the phase shift film formed thereon was introduced again into the sputtering apparatus. Using a target of chromium and a gas mixture of argon (Ar), carbon dioxide (CO₂), and helium (He) (flow rate ratio Ar:CO₂:He=16:30:30, pressure of 0.2 Pa) as a sputtering gas, DC sputtering was carried out to form, on the phase shift film, a light shielding film made of a CrOC film (Cr: 71 atomic %, O: 15 atomic %, C: 14 atomic %) containing chromium, oxygen, and carbon to a thickness of 48 nm. Thus, a chromium-based light-shielding film as a single layer was formed.

A stacked structure of the phase shift film and the light-shielding film (CrOC film) had the optical density of 3.5 with respect to the exposure light of the ArF excimer laser (wavelength of 193 nm).

Next, the transparent substrate with those films through the light-shielding film formed thereon was placed in the single-wafer DC sputtering apparatus. In the same manner as that of Example 1, a hard mask layer made of an SiON film containing silicon, oxygen and nitrogen was formed on the light-shielding film.

As described above, the mask blank of Comparative Example 1 was manufactured.

On the surface of the mask blank of Comparative Example 1, that is, the surface of the hard mask layer, a central region 21 was defined as an inner region of 1-μm square positioned with respect to the center of the substrate. In the central region 21, AFM measurement was performed. From a measurement result, the arithmetic mean roughness Sa, the maximum height Sz, and the value of Sz/Sa were calculated. As a result, in the mask blank of Comparative Example 1, Sa=0.515 nm, Sz=11.1 nm, Sz/Sa=21.55. The root mean square roughness Sq in the central region 21 was 0.681 nm.

On the surface of the hard mask layer of the mask blank in Comparative Example 1, eight adjacent regions 22, each being an inner region of 1-μm square, was defined so as to be in contact with the outer periphery of the central region 21. In the adjacent regions 22, AFM measurement was performed to measure Sa and Sz in all of the adjacent regions 22. As a result, Sa was 1.0 nm or less and all values of Sz/Sa were greater than 14 in all of the adjacent regions 22.

Furthermore, the surface of the mask blank in Comparative Example 1 was subjected to defect inspection in a pattern-forming region which is an inner region of 132-mm square by the defect inspection apparatus Teron (manufactured by KLA) using inspection light having a wavelength of 193 nm. As a result, many microdefects occurred and the number of the defects was enormous so that the inspection was terminated (overflow) in the middle of the inspection.

From the foregoing, if the mask blank does not satisfy the conditions of the present disclosure that Sa is 1.0 nm or less and Sz/Sa is 14 or less in the central region 21, like the mask blank of Comparative Example 1, it is not possible to assure that the mask blank has few microdefects (for example, the number such that no adverse effect is given upon carrying out the defect inspection, for example, 100 or less) in at least the pattern-forming region of the pattern-forming thin film.

### DESCRIPTION OF REFERENCE NUMERALS

1 transparent substrate
2 pattern-forming thin film
3 resist film
5 chromium nitride-based layer
6 upper layer
7 hard mask layer
8 phase shift film
10, 30 mask blank
20 transfer mask (binary mask)
21 central region
22 adjacent region
40 transfer mask (halftone phase shift mask)

1. A mask blank having a substrate and a pattern-forming thin film formed on the substrate,
wherein the pattern-forming thin film is one of a single-layer film containing chromium and nitrogen or a multi-layer film comprising at least one chromium nitride-based layer; and
wherein an arithmetic mean roughness Sa is 1.0 nm or less and a ratio of a maximum height Sz to the arithmetic mean roughness Sa Sz/Sa is 14 or less in a 1-μm square positioned in a central region on a surface of the pattern-forming thin film with respect to a center of the substrate.

2. The mask blank according to claim 1, wherein, eight adjacent regions, each of which is a non-overlapping 1-μm square and is in contact with an outer periphery of the central region, have an arithmetic mean roughness Sa of 1.0 nm or less and a ratio of a maximum height Sz to the arithmetic mean roughness Sa Sz/Sa of 14 or less.

3. The mask blank according to claim 1, wherein the maximum height Sz of the central region is 10 nm or less.

4. The mask blank according to claim 1, wherein a root-mean-square roughness Sq of the central region is 1.0 nm or less.

5. The mask blank according to claim 1, wherein, when the surface of the pattern-forming thin film is subjected to defect inspection by a defect inspection apparatus using inspection light having a wavelength of approximately 193 nm to obtain distribution of convex defects in a pattern-forming region which is an inner region of 132-mm square, microdefects being the convex defects having a height of 10 nm or less are present in the pattern-forming region and the number of the microdefects present in the pattern-forming region is 100 or less.

6. The mask blank according to claim 1, wherein when the pattern-forming thin film is the single-layer film containing chromium and nitrogen, a content of nitrogen in a portion of the single-layer film excluding a surface layer on opposite from the substrate is 8 atomic % or more, or when the pattern-forming thin film is the multi-layer film, a content of nitrogen in the at least one chromium nitride-based layer of the multi-layer film is 8 atomic % or more.

7. The mask blank according to claim 1, wherein when the pattern-forming thin film is the single-layer film containing chromium and nitrogen, a content of chromium in a portion of the single-layer film excluding a surface layer opposite from the substrate is 60 atomic % or more, or when the pattern-forming thin film is the multi-layer film, a content of chromium in the at least one chromium nitride-based layer of the multi-layer film is 60 atomic % or more.

8. The mask blank according to claim 1. wherein the pattern-forming thin film is the multi-layer film, and the pattern-forming thin film further comprises a hard mask layer containing silicon and oxygen on the at least one chromium nitride-based layer.

9. The mask blank according to claim 1, wherein the pattern-forming thin film is the multi-layer film, and the multi-layer film further comprises at least one additional layer containing chromium and nitrogen on a surface of the at least one chromium nitride-based layer.

10. The mask blank according to claim 9, wherein the multi-layer film further includes a hard mask layer containing silicon and oxygen on a surface of the at least one additional layer.

11. The mask blank according to claim 1, further comprising a phase shift film between the substrate and the pattern-forming thin film.

12. The mask blank according to claim 11, wherein the phase shift film transmits exposure light of an ArF excimer laser (wavelength of approximately 193 nm) at a transmittance of 8% or more, and a function of generating generates a phase difference of 150 degrees or more and 210 degrees or less with respect to the exposure light of the ArF excimer laser.

13. The mask blank according to claim 11, wherein an optical density of a stacked structure comprising the phase shift film and the pattern-forming thin film, with respect to exposure light of an ArF excimer laser (wavelength of approximately 193 nm), is 3.3 or more.

14. A method of manufacturing a transfer mask using a mask blank having a substrate and a pattern-forming thin film formed on the substrate, including:
forming a transfer pattern on the pattern-forming thin film by dry etching using a resist pattern as a mask,
wherein the pattern-forming thin film is one of a single-layer film containing chromium and nitrogen or a multi-layer comprising at least one chromium nitride-based layer, and
wherein an arithmetic mean roughness Sa is 1.0 nm or less and a ratio of a maximum height Sz to the arithmetic mean roughness Sa Sz/Sa is 14 or less in a 1-μm square positioned in a central region on a surface of the pattern-forming thin film with respect to a center of the substrate

15. A method of manufacturing a transfer mask using a mask blank a substrate, a phase shift film on the substrate, and a pattern-forming thin film on the phase shift film, including:
forming a transfer pattern on the pattern-forming thin film by dry etching using a resist pattern as a mask, and
forming a transfer pattern on the phase shift film by dry etching using the pattern-forming thin film having the transfer pattern as a mask,
wherein the pattern-forming thin film is one of a single-layer film containing chromium and nitrogen or a multi-layer comprising at least one chromium nitride-based layer, and
wherein an arithmetic mean roughness Sa is 1.0 nm or less and a ratio of a maximum height Sz to the arithmetic mean roughness Sa Sz/Sa is 14 or less in a 1-μm square positioned in a central region on a surface of the pattern-forming thin film with respect to a center of the substrate.

16. A method of manufacturing a semiconductor device, including a step of carrying out exposure transfer of a transfer pattern to a resist film on a semiconductor substrate by using a transfer mask obtained by the method of manufacturing a transfer mask according to claim 14.

17. The mask blank according to claim 9, wherein the at least one additional layer further comprises oxygen.
